(19) United States
(12) Patent Application Publication
(10) Pub. No.: US 2011/0084324 A1
(43) Pub. Date: Apr. 14, 2011

(54) RADIATION HARDENED MOS DEVICES AND METHODS OF FABRICATION

(75) Inventors: Emily Ann Donnelly, Sachse, TX (US); Byron Neville Burgess, Allen, TX (US); Randolph W. Kahn, McKinney, TX (US); Todd Douglas Stubblefield, Sherman, TX (US)

(73) Assignee: TEXAS INSTRUMENTS INCORPORATED, Dallas, TX (US)

(21) Appl. No.: 12/576,441

(22) Filed: Oct. 9, 2009

(51) Int. Cl. H01L 27/06; H01L 29/78; H01L 27/092; H01L 21/8238; H01L 21/8249; H01L 21/762

(52) U.S. Cl. 257/296; 257/409; 257/369; 257/378; 438/225; 438/207; 438/297; 257/E29.255; 257/E27.016; 257/E27.062; 257/E27.015; 257/E21.642; 257/E21.696; 257/E21.552

(57) ABSTRACT

Radiation hardened NMOS devices suitable for application in NMOS, CMOS, or BiCMOS integrated circuits, and methods for fabricating them. A device includes a p-type silicon substrate, a field oxide surrounding a moat region on the substrate tapering through a bird's beak region to a gate oxide within the moat region, a heavily-doped p-type guard region underlying at least a portion of the bird's beak region and terminating at the inner edge of the bird's beak region, a gate crossing the moat region, and n-type source and drain regions spaced by a gap from the inner edge of the guard region. A variation of a local oxidation of silicon process is used with an additional bird's beak implantation mask as well as minor alterations to the conventional moat and n-type source/drain masks. The resulting devices have improved radiation tolerance while having a high breakdown voltage and minimal impact on circuit density.

### BACKGROUND OF THE INVENTION

1. Field of the Invention

The present invention relates generally to the field of semiconductor device manufacturing, and more particularly, to variations on the local oxidation of silicon process for isolation of NMOS transistors in integrated circuits having improved radiation hardness and high breakdown voltages.

2. Description of the Related Art

Local oxidation of silicon (LOCOS) fabrication processes are used to provide electrical isolation between devices in integrated circuits (ICs). Variations of such processes are known by several names and may be used to fabricate complementary metal oxide semiconductor (CMOS) as well as n-type metal oxide semiconductor (NMOS) circuits and CMOS circuits incorporating bipolar junction transistors (BiCMOS). In these processes, a thick field oxide is thermally grown in isolation regions between adjacent semiconductor devices that are formed in so-called active or “moat” regions under a thin oxide.

LOCOS processes have the advantage of being largely self-aligned, allowing the production of high-density circuits with high manufacturing yield, but there are known issues with this isolation technique. Among the typical issues which must be addressed is the leakage of unintended active parasitic devices turned on by voltage in interconnect lines over the field oxide, which can occur at voltages close to the operating voltage if the doping concentration is low underneath the field oxide. To combat this effect, a common technique is to heavily dope the isolation region before the field oxide is grown to form a “channel stop.” This enables the threshold voltage of the isolation region to be raised above the operating voltage of the circuit, preventing parasitic leakage.

It is also well known that MOS circuits formed using a LOCOS process are not tolerant of ionizing radiation such as may be encountered in space, in nuclear power plants, or in the vicinity of a nuclear explosion. When a MOS device is exposed to ionizing radiation, electron-hole pairs are generated in the various oxide regions, resulting in trapped charge and interface states. Due to the materials involved, the effect is a cumulative buildup of positive charge in the oxide, leading to large negative threshold shifts and thus to leakage particularly in parasitic devices associated with NMOS transistors. This leakage leads at least to increased power dissipation, and in a worst case can lead to a failure of operation of the device that incorporates the NMOS transistor. Thinner oxide regions within the isolation region have lower threshold voltages to begin with and are thus most susceptible to this type of leakage. While techniques exist for growing radiation hard gate oxide material, the thicker field oxide regions are not susceptible to these measures. Increasing the doping of the channel stop to preclude the possibility of radiation-induced inversion layers extending between devices can result in unacceptably low drain-to-substrate breakdown voltages in conventional designs in which the p-type channel stop abuts the n-type source and drain regions. There is also a tapered region where the thick field oxide tapers down to the thickness of the gate oxide called the “bird's beak” region. Part of this tapered region is an encroachment region, which forms under the edge of the silicon nitride mask for the moat region during field oxide growth surrounding a MOS transistor. Here, due to its being thinner, its associated parasitic threshold voltage is lower than that of the field oxide, and the usual channel stop implant used to increase the threshold voltage in the field regions does not reach under the nitride. Moreover, pulling the channel stop away from the moat region to increase breakdown voltage further decreases the dopant concentration in the bird's beak region and the channel region under the gate, leading to increased source-to-drain leakage from these two paths.

Solutions to prevent parasitic leakages between and within devices by simply using higher doping to increase threshold voltages result in decreased breakdown voltages. Thus numerous radiation tolerant designs have been proposed and implemented involving layouts incorporating heavily-doped guard rings or guard bands, and increased separation of N+ and P+ regions to increase breakdown voltage and counter high capacitance. Hence, these designs face tradeoffs and are typically significantly larger and/or slower than the unmodified devices. For example, Hatano et al. (H. Hatano and S. Takatsuka, “Total dose radiation-hardened latch-up free CMOS structures for radiation-tolerant VLSI designs,” IEEE Trans. Nucl. Sci., Vol. NS-33, No. 6, December 1986, pp. 1505-1509) describe several NMOS transistor structures that utilize a P+ guard ring structure within the moat regions and a large space between the N+ source and drain and the guard ring. Lund et al. (U.S. Pat. No. 4,591,890) describe a highly-doped P+ guard region under the field oxide, setting the n-type source and drain well inside the moat region, and a special gate structure to avoid dopant contamination of the separation region. Owens et al. (U.S. Pat. No. 5,220,192) describe moderately-doped p-type regions under the field oxide in addition to p-type guard bands extending into the moat region under the thin gate oxide, also with separation between the guard bands and the N+ source and drain. Groves et al. (U.S. Pat. No. 6,054,367) describe methods of improving the radiation hardness of the bird's beak region by increasing the impurity concentration specifically within that region using masking and implantation, but do not counteract a reduction in breakdown voltage resulting from these steps.

There is accordingly a need to further improve the radiation hardness of MOS devices and particularly the NMOS component thereof, while retaining or improving breakdown voltages and with minimal impact on circuit density or additional complexity of design.

### SUMMARY OF THE INVENTION

These and other problems associated with the prior art are addressed by the present invention, which provides MOS devices having improved radiation hardness of the bird's beak region by reducing radiation-induced leakage along the bird's beak leakage path while retaining a high breakdown voltage, and methods of fabricating these devices and integrated circuits incorporating them. This is accomplished by doping the bird's beak region to higher levels than permitted previously, specifically in the areas underlying where gate lines cross the bird's beak region, which increases the threshold voltage of the bird's beak region, and by pulling back the source and drain from the edge of the bird's beak into the moat region to increase the breakdown voltage while retaining a predetermined electrical width. A variation of a LOCOS process is used with an additional bird's beak implantation mask as well as alterations to the conventional moat and n-type source/drain masks.

The present invention can be used to improve the radiation hardness of NMOS, CMOS, or BiCMOS integrated circuits produced using variations of a LOCOS technology. Digital, analog, or mixed-signal circuits can be implemented using the devices and processes provided herein. Devices produced in accordance with the present invention operate at speeds and current levels comparable to conventional unmodified NMOS transistors, while having a minimal impact on transistor size and thus circuit density. Breakdown voltages are maintained or even improved, thus allowing high voltage operation of circuits produced in accordance with the present invention.

More specifically, the present invention provides a radiation hardened MOS device. The device includes a p-type silicon substrate, a field oxide surrounding a moat region on the substrate tapering through a bird's beak region to a gate oxide within the moat region, a heavily-doped p-type guard region underlying at least a portion of the bird's beak region and terminating at the inner edge of the bird's beak region, a gate crossing the moat region, and n-type source and drain regions spaced by a gap from the inner edge of the guard region.

The present invention also provides a method of fabricating a radiation hardened MOS device by providing a silicon substrate with a P− layer within the top surface and a pad oxide layer on the top surface, and then forming a masking layer to define a moat region. Then the substrate is oxidized to form a field oxide layer in areas not covered by the masking layer, terminating in a bird's beak region extending beneath the masking layer. The masking layer and pad oxide are removed, and a gate oxide is formed within the moat region. A p-type impurity is implanted into the substrate beneath the bird's beak region but not extending into the moat region under the gate oxide. A gate is then formed overlying the gate oxide and extending in the width direction across the moat region, defining a channel area and crossing the bird's beak region onto the field oxide on at least one edge of the moat region. An n-type impurity is implanted into source and drain regions that are spaced away from the bird's beak region by a gap while having a width along the channel area that is equal to a predetermined electrical width. The fabrication of the radiation hardened MOS device is then completed on the substrate.

The present invention additionally provides an integrated circuit (IC) device fabricated according to the method just described and that includes one or more devices in addition to a radiation hardened MOS device.

Other features and advantages of the present invention will be apparent to those of ordinary skill in the art upon reference to the following detailed description taken in conjunction with the accompanying drawings.

### DESCRIPTION OF THE VIEWS OF THE DRAWINGS

The above and further advantages of the invention may be better understood by referring to the following description in conjunction with the accompanying drawings, in which:

FIG. 1 is a cross-sectioned isometric view of an NMOS transistor showing three radiation-induced leakage paths;

FIG. 2A depicts a mask layout for a radiation-hardened MOS device in accordance with one embodiment of the present invention;

FIG. 2B shows a cross-sectional view of the radiation-hardened MOS device of FIG. 2A;

FIG. 2C shows another cross-sectional view of the radiation-hardened MOS device of FIG. 2A;

FIG. 3 depicts a mask layout for a radiation-hardened MOS device in accordance with an alternate embodiment of the present invention;

FIG. 4 depicts a mask layout for a radiation-hardened MOS device in accordance with another embodiment of the present invention;

FIG. 5 depicts a mask layout for a radiation-hardened MOS device in accordance with yet another embodiment of the present invention;

FIG. 6 is a flow chart illustrating a process flow for fabricating a radiation-hardened MOS device according to the principles of the present invention;

FIGS. 7A through 7H show cross-sectional views of a portion of an MOS integrated circuit illustrating various stages in a process used to produce a radiation-hardened MOS device in accordance with one embodiment of the present invention; and

FIG. 8 is a cross-sectioned isometric view of a portion of an MOS integrated circuit illustrating the integration of a radiation hardened NMOS transistor with a PMOS transistor in accordance with another embodiment of the present invention.

### DETAILED DESCRIPTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

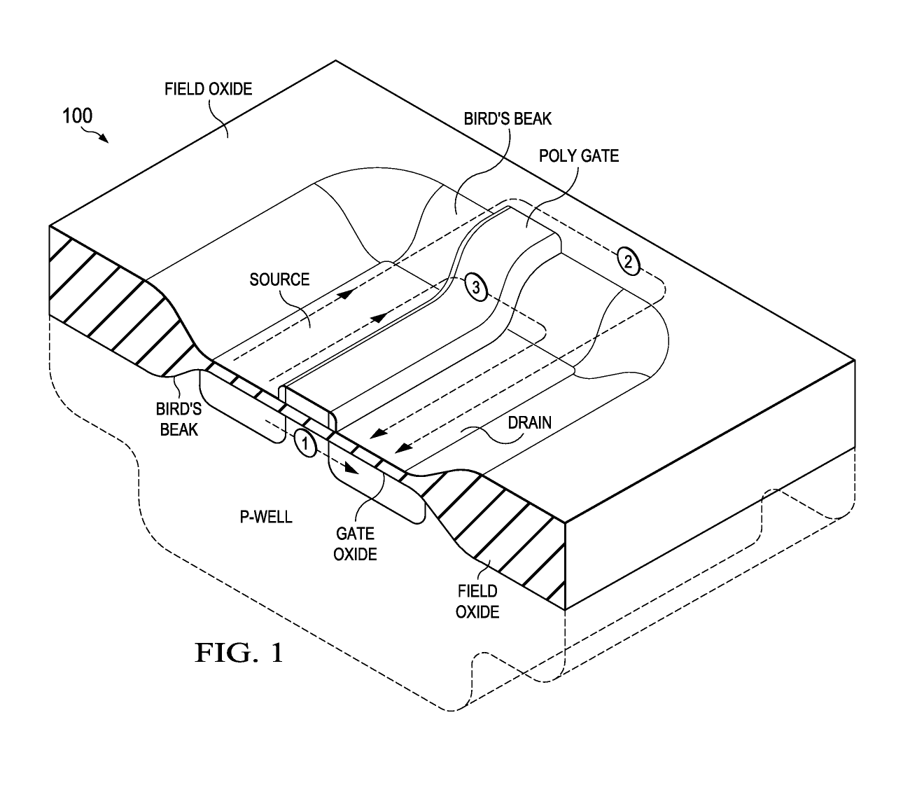

Referring to FIG. 1, there is shown a cross-sectioned isometric view of a typical NMOS transistor device 100 which can be part of an integrated circuit having multiple such transistors such as an NMOS device, a CMOS device (the PMOS transistor not being shown), or a BiCMOS device (which would additionally include bipolar junction transistors. In the illustrated device, the NMOS transistor is formed in a “p-well” which is a lightly doped p-type region formed within a silicon substrate. Alternatively, an entire top layer several micrometers thick or more of the silicon substrate can be lightly doped p-type material. The device 100 as illustrated in FIG. 1 is typical of one produced using a local oxidation of silicon (LOCOS) process used for isolating devices. It can be seen that a source and drain region are formed within a so-called “moat region” covered by a thin gate oxide, and surrounded by an isolating field oxide. Typical thicknesses for these oxides are in the range of 75 to 500 angstroms for a gate oxide and 8000 to 10000 angstroms for a field oxide. The transition region at the edge of the moat in which the oxide thickness tapers from the thin gate oxide to the thick field oxide is known as the “bird's beak” region as suggested by its shape in the cross-section. Three radiation-induced source-to-drain current leakage paths that can be caused by threshold voltage shifts are shown: path 1 under the gate oxide layer, path 2 under the field oxide layer, and path 3 under the bird's beak region. Field oxide leakage is commonly controlled using a channel stop implant to place p-type impurity (not shown) under the field oxide before the oxidation step, gate oxide leakage may be controlled by controlling the properties of the gate oxide material, and solutions for bird's beak leakage are of primary relevance and interest herein.

Well known in the present art are the designations “P−”, “P”, and “P+” to describe ranges of doping concentrations of p-type dopants, and “N−”, “N”, and “N+” to describe ranges of doping concentrations of n-type dopants, where “P−” and “N−” refer to doping concentrations of 10¹⁴-10¹⁶ cm⁻³, “P” and “N” refer to concentrations of 10¹⁶-10¹⁹ cm⁻³, and “P+” and “N+” refer to concentrations of 10¹⁹-10²¹ cm⁻³. These dopant concentrations can be introduced into the substrate by a number of different processes, but ion implantation will be described herein as an example process capable of placing the dopants precisely where they are required. For a given implant energy, peak volumetric concentrations are approximately proportional to the “dose” of the implant, given in units of cm⁻², which is a quantity easily specified during processing.

In an NMOS transistor 100 as shown in FIG. 1, the source and drain consist of heavily-doped N+ regions implanted into a lightly-doped P− substrate, surface layer, or well. The region under the gate is called the “channel,” the dimension of the gate in the direction from source to drain (as indicated by path 1) is called the “length,” and the dimension of the source and drain sideways along the gate is called the “width.” These dimensions determine the performance characteristics of the transistor; for example, a MOS transistor device with a larger width can pass more current for the same applied gate voltage, all other variables being the same. Therefore, these dimensions are specified during the design of circuits using such devices, and alterations to the device design, e.g. to improve radiation hardness, should leave dimensions such as the width approximately unchanged in order for the device to behave the same in a circuit. In designs for a conventional LOCOS process, the mask pattern for the source and drain (“n-source/drain” or NSD for an NMOS device) may be oversized from the moat pattern in order to take advantage of self-alignment of the edges of moat offered by the field oxide acting as a masking layer for the n-type implant, and the edges of the source and drain next to the gate are similarly self-aligned since they are masked by the gate itself.

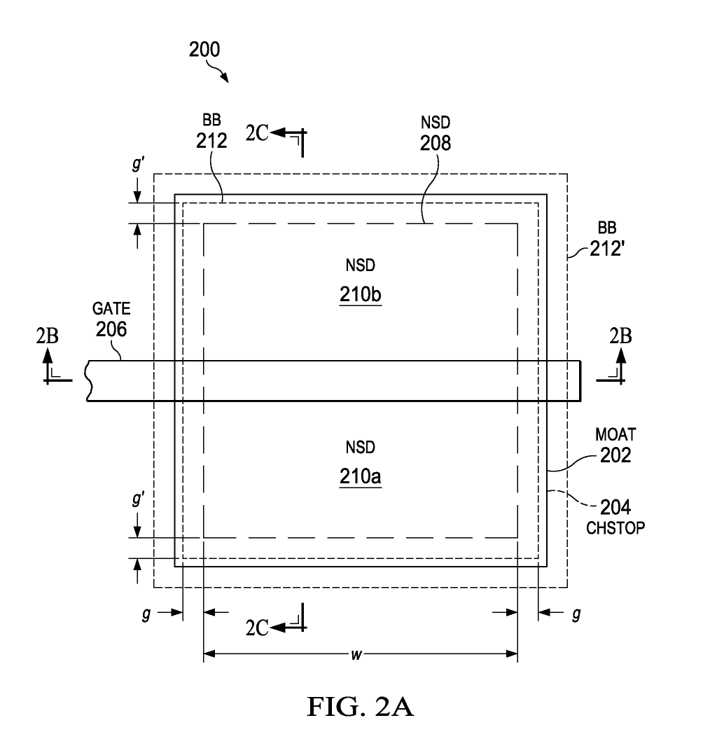

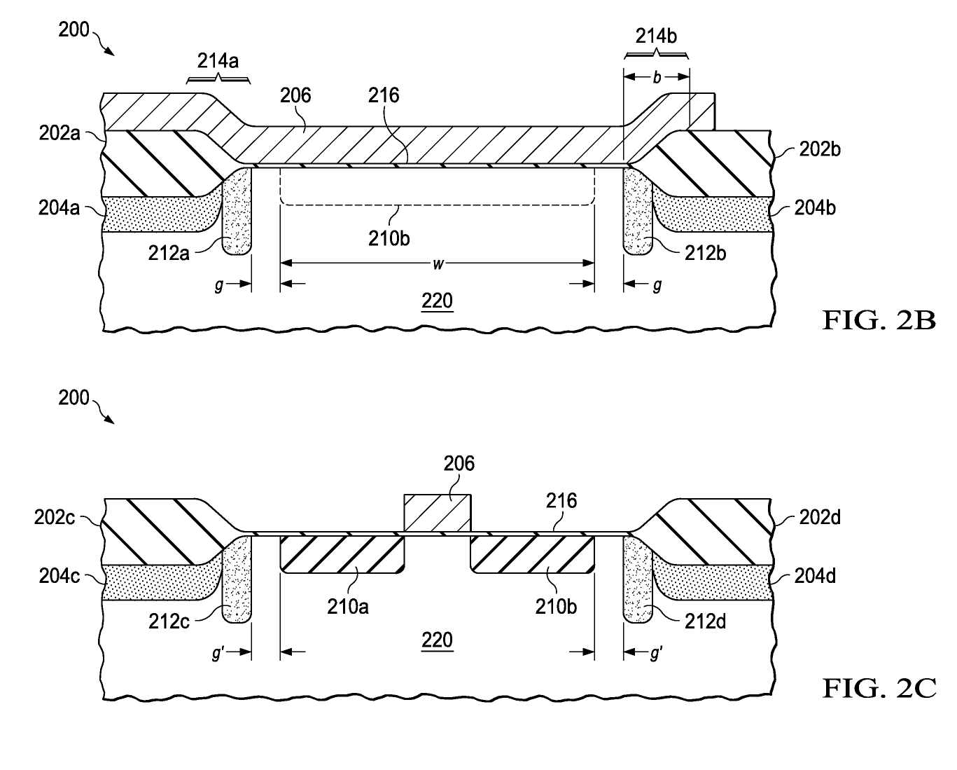

In the following discussion, like reference numerals will be used in the different figures and views to refer to like structures and features. Further, when there is no risk of confusion from doing so, the same reference numeral will be used to refer to a device structure or feature as to its representation on a mask layout. For example, reference numeral 200 will refer both to a device and to a mask layout for the device, and reference numeral 206 will be used to refer both to the outline of the gate on the mask layout in FIG. 2A and to cross-sectional views of the fabricated gate structure in FIGS. 2B and 2C. If needed, similar features occurring in different positions within the device or drawing are given letters following the reference numeral such as 210a and 210b.

Now referring to FIG. 2A, a mask layout corresponding to an idealized plan view for a radiation hardened MOS device 200 according to one embodiment of the present invention is shown. The plan view is idealized in the sense that the exact dimensions of the structures that are formed during fabrication may vary slightly from the dimensions projected onto the wafer during photolithography, as is well known to those skilled in the art. The structures shown on the mask are sized and positioned so as to take these types of variations into account. Although a simple rectangular geometry is shown, as will be appreciated by those skilled in the art, many other shapes and variations are possible. A legend is provided to help identify mask layout patterns by different line types and fill patterns. Mask 202 for the moat (labeled MOAT in the legend) is used to define the inner edges of the field oxide. This mask is sometimes referred to as an “inverse moat” mask because it codes for areas where the moat region is absent. Channel stop mask 204 (CHSTOP) defines the inner edges of the channel stop implant, gate mask 206 (GATE) defines the gate shape, n-source/drain mask 208 (NSD) defines the outer edges of the n-source/drain implant. The CHSTOP pattern 204 associated with an NMOS device is often coincident with the MOAT pattern 202 in this area of a layout, and this is the way it is shown in FIG. 2A, making the CHSTOP edge indistinguishable in the drawing from MOAT. Bird's beak mask 212 (BB) defines the inner edge of the bird's beak implant. An optional feature on the BB mask is outer edge 212′ as shown for this embodiment, forming a “picture frame” pattern for BB. This outer edge feature may be absent, and the BB pattern may extend outward throughout the entire CHSTOP pattern if additional doping of the CHSTOP area by the BB implant is deemed useful or if an alternative masking and process sequence is used. Usually, a field oxide is too thick for a BB implant to penetrate in order for significant additional doping to be accomplished in the CHSTOP areas in a preferred process flow in which BB implant occurs after field oxidation. Together with GATE 206, NSD 208 defines two source/drain areas 210a and 210b (functionally interchangeable until their identity as source or drain is established by their use in a circuit) Inner edge 212 of BB is seen to overlap inside MOAT 202 by a small amount corresponding to the extent of “encroachment” that the bird's beak region grows under the physical nitride moat mask during field oxidation, in order to align the inner edge of the bird's beak implant with the inner edge of the bird's beak region, where the tapering bird's beak oxide interfaces with or transitions to the gate oxide. In this encroachment area, the channel stop implant fails to introduce any doping because it is blocked by nitride and resist within the outline of the MOAT region. NSD mask 208 is deliberately undersized (or “pulled back” into the moat region) with respect to BB 212 in order to create a gap between the NSD implant and the BB implant. The amount of this gap is shown to be g on the left and right hand sides, and g′ on the top and bottom sides. The purpose of these gaps is to increase the drain-to-substrate breakdown voltage BV_{DSS} above what is possible were the NSD doping regions in contact with the BB doping regions. The choice of the dimension of these gaps depends on the desired breakdown voltage to allow circuit operation at a particular supply voltage. An exemplary value for g or g′ might be 1 micrometer or greater for logic circuits operating at 5 V supply voltage. The more critical gap is g because leakage is most likely to occur between source and drain 210a and 210b on the left and right edges, and particularly under the gate 206, which is closer to the surface of the substrate than e.g. metal interconnect lines connected to source and drain contacts (not shown) that traverse the bird's beak region on the top and bottom edges. Likewise, the left and right side bird's beak implants are more important, particularly in proximity to and underneath where the gate 206 crosses over the bird's beak region. Finally, if a transistor is needed in a circuit design that has a particular electrical width w, the NSD regions must be sized after incorporating these gaps g into the layout such that they have width w along the gate as shown. Two section lines labeled 2B-2B (for which FIG. 2B is a representative section) and 2C-2C (for which FIG. 2C is a representative section) are also shown.

FIG. 2B shows a section of device 200 taken through the width direction of polysilicon gate 206, showing oxide structures and implants created using the mask layout of FIG. 2A and a process to be described later. As in FIG. 1, field oxide regions 202a and 202b on either side of the moat region can be seen, tapering through bird's beak regions 214a and 214b to the thickness of gate oxide 216, which gate 206 overlies. The width of a bird's beak region is shown to be b using region 214b as an example. Channel stop implants 204a and 204b lie in the substrate beneath field oxide regions 202a and 202b, respectively, and are shown extending to a point within the tapered region of each bird's beak. Bird's beak implant structures 212a and 212b underlie bird's beak regions 214a and 214b, their inner edges (defined to be those toward the gate oxide) substantially aligned with inner edges of the bird's beak regions. Their outer edges are contiguous in this example with the inner edges of the channel stop regions 204a and 204b. The exact location defined for this transition is variable and depends on the thickness of the oxide at this point in the tapered region, bird's beak implant energy, and bird's beak mask design incorporating device spacings and other design rules instituted to ensure that the channel stop performs its function. The bird's beak implanted regions 212a and 212b are shown as deeper than the channel stop because the implants are performed at a higher energy, and also because the field oxidation step consumes some of the channel stop implant impurity, which is typically performed before the field oxidation. Source/drain region 210b is shown in dashed lines because there is no n-type impurity directly under gate 206 through which this section is taken. Width of the source/drain 210b is w and there is a gap g on either side between source/drain 210b and bird's beak implants 212a and 212b.

FIG. 2C shows a section of device 200 taken through the length direction of the channel area under the gate 206. This view shows the source and drain implants 210a and 210b clearly underlying gate oxide 216 and on either side of a channel area under gate 206. The cross section cuts through different sides of the field oxide 202c and 202d, under which lie channel stop implant regions 204c and 204d, respectively. In general, the bird's beak implant regions 212c and 212d on these sides may be different in position and extent than in the critical regions under the gate, or entirely absent in other embodiments, and may also, as already discussed, have a different spacing g′ from the source/drain regions 210a and 210b.

Experiments were performed on devices fabricated according to the designs and processes of the present invention, using a structure similar to that of FIG. 2A, to verify the effectiveness of the present invention in yielding functional devices, increasing breakdown voltage, and improving radiation hardness. Table 1 below shows average results for breakdown voltage drain to substrate (BV_{DSS}) over a number of wafers in lot splits having the parameters indicated, and processed using a variation of a standard 5 V CMOS logic process. It is desired to raise the breakdown to over 20 V for use with linear BiCMOS processes. The amount of NSD pullback g=g′ was varied from 0 to 2 μm, and the channel stop and bird's beak implant doses using a pattern like that in FIG. 2A were varied over the ranges shown in the table:

TABLE 1
Breakdown voltage BV_{DSS} as a function
of implant doses and NSD pattern pullback.

| | | BB | | | | | |
|---|---|---|---|---|---|---|---|
| NSD | CHSTOP | Dose | | | | | |
| Pullback | Dose | (×10¹³ cm⁻²) | | | | | |
| (μm) | (×10¹⁴ cm⁻²) | 0 | 0.8 | 1.0 | 2.0 | 3.0 | 4.0 |
| 0 | 0.3 | 13.9 | | | | | |
| | 2.0 | | | | 8.7 | 8.1 | |
| | 2.5 | | | 9.2 | 8.4 | 7.9 | |
| | 3.0 | | 9.0 | | | | |
| 1.6 | 2.0 | | | | 15.0 | 15.0 | 15.0 |
| 2.0 | 2.0 | | | | 15.2 | 14.9 | 15.1 |

It can be seen that breakdown voltage is improved over the baseline even at high BB doses for an NSD pullback of 1.6 μm or more. Without pullback, BB doses of over 1×10¹³ cm⁻² lead to a lowered breakdown voltage. Yield data (not shown) also have shown that without NSD pullback, yield drops off for BB doses increasing over 1×10¹³ cm⁻². In conjunction with the pullback, BB doses can be increased in this process to over 4×10¹³ cm⁻² thus lowering BB leakage without breakdown voltage. Experiments with radiation exposure have verified low leakage current with exposure to total radiation doses of up to 120 krad for NSD spacings of 1.6 and 2.0 μm, and BB doses of 4×10¹³ cm⁻², as in the lower-right corner of Table 1, where with no pullback, leakage increases below 50 krad because BB doses are limited to 1×10¹³ cm⁻² before breakdown becomes a problem.

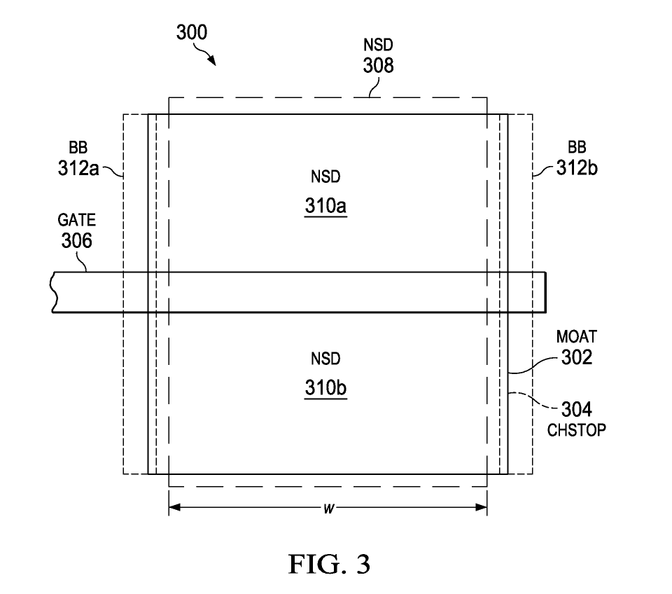

Now referring to FIG. 3, a mask layout for another embodiment of a radiation hardened MOS device 300 according to the present invention is shown, in which the non-critical sections of the bird's beak implant on the top and bottom sides of the moat region 302 are deleted. This design takes advantage of the fact already observed that leakage is a lesser problem on the edges not crossed by the gate, thereby not requiring a bird's beak implant along those edges. Bird's beak implant areas 312a and 312b are limited to the left and right edges of the moat region, each extending along an entire edge of the moat region. Here the channel stop pattern 304 (CHSTOP) is again coincident with the moat pattern 302 (MOAT), and thus obscured in the drawing by the solid line assigned to MOAT. Thus this device would have a similar cross-section through gate 306 in the width direction to FIG. 2B. The non-essential top and bottom edges have been modified to allow the NSD pattern 308 to overlap the moat 302 in order to simplify alignment in that direction. In this case, the NSD mask defines the left and right edges of source/drain regions 310a and 310b, but the moat edge defines the source/drain extent on the top and bottom edges. In the top-to-bottom (length) direction, in the encroachment area, the channel stop implant fails to introduce any doping because it is blocked by nitride and resist within the outline of the MOAT region. Thus there is a natural gap between the n-source/drain implanted region and the channel stop implanted region, so that breakdown voltage is not significantly impaired by this pattern.

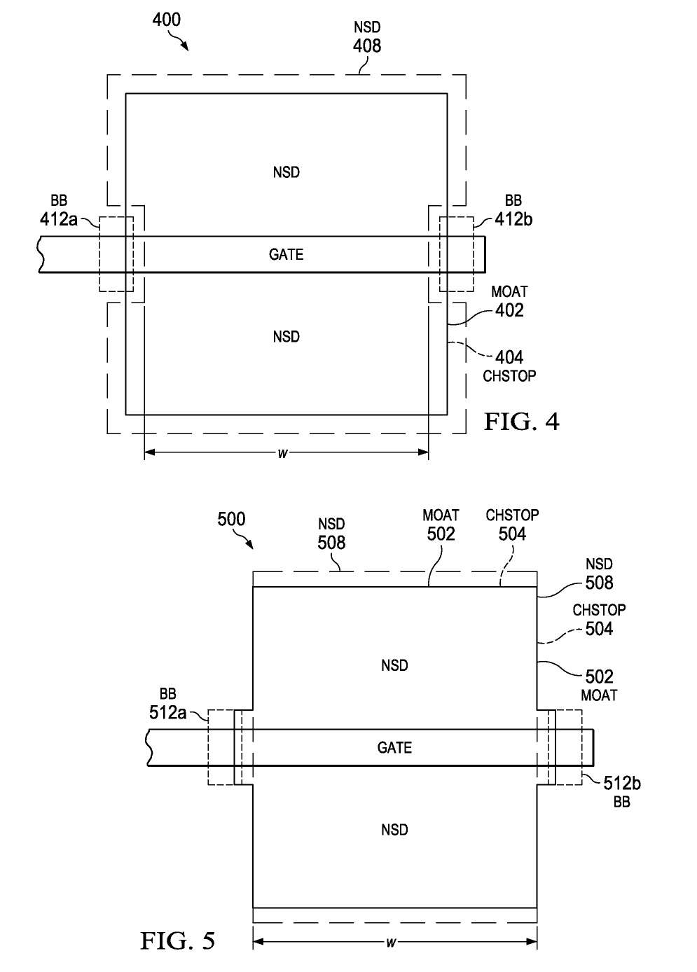

FIG. 4 shows a mask layout for another embodiment of a radiation hardened MOS device 400. While maintaining electrical width w, the source/drain NSD pattern 408 has been shaped to allow maximum overlap for moat self-alignment. This is accomplished by reducing the extent of the bird's beak regions 412a and 412b to a minimum length that still achieves a desired reduction of bird's beak leakage given the circuit operating conditions and radiation conditions. Again, the patterns for MOAT 402 and CHSTOP 404 lie on top of each other.

FIG. 5 shows a mask layout for yet another embodiment of a radiation hardened MOS device 500 designed to minimize moat area and hence device size and spacing for maximum circuit density. In this case, the moat pattern 502 is made equal in width to the desired electrical width w similar to a conventional design, but is shaped to set back the bird's beak segments 512a and 512b in a similar fashion to the short segments shown in FIG. 4. CHSTOP 504 is again coincident with MOAT 502. NSD mask 508 is allowed to overlap MOAT 502 on top and bottom edges although alignment is slightly more critical on the left and right than for device 400, since a poor overlap in the left-to-right (width) direction in this case can alter the aperture of the overlap of MOAT and NSD that now defines electrical width w.

As will be appreciated by those skilled in the art, many other layout variations are possible that achieve low bird's beak leakage by increasing the doping under the bird's beak region in the vicinity of gate crossings, and also keep breakdown voltage high by spacing the source and drain regions away from the bird's beak region.

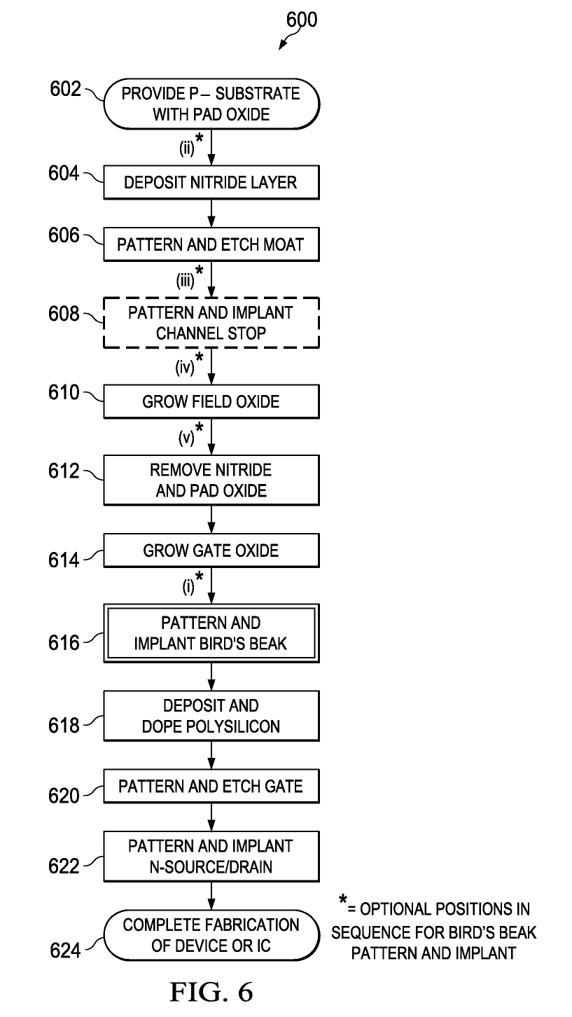

Now referring to FIG. 6, a flow chart illustrating an exemplary process flow 600 suitable for fabricating a radiation hardened MOS device according to the principles of the present invention is shown. This is a basic flow including essential steps and a few required for illustration. Not shown in the flow chart are optional process steps to form additional types of devices, such as PMOS or bipolar transistors, or other devices such as diodes, resistors, and capacitors; or to form circuits such as CMOS, BiCMOS integrated circuits on the same wafer in conjunction with the devices of the present invention; or to adjust the performance of the NMOS devices. Such additional steps may be used in conjunction with, but are not essential to, the practice of the present invention. There are also steps well known in the art for improving device reliability such as the growth of dummy or sacrificial oxides before threshold adjusting implants, or cap oxides over the polysilicon gates, which have been omitted where they do not affect the essential steps. In addition, some combinations of basic steps have been included in the steps shown. For example, an “implant” step includes any subsequent annealing, activation, or diffusion step that may be required to form desired profiles and concentrations, and any “pattern & implant” or “pattern & etch” block should be understood to include a resist strip afterwards, which in itself may consist of several detailed steps.

Process 600 begins in block 602 by providing a lightly doped p-type silicon substrate with a pad oxide layer deposited upon its top surface. As explained earlier, the substrate may be a uniformly doped substrate, but is preferably a heavily-doped substrate (for example P+) with a lightly-doped epitaxial layer several micrometers thick on top (for example, P− or “p-epi”). It can also be an n-type wafer having p-wells formed in it in which the subsequent process for NMOS transistors will be implemented, as illustrated in FIG. 1. A nitride layer is deposited in block 604, and then patterned and etched using the MOAT pattern in block 606. As widely accepted terminology, “patterning” refers to the process of applying, exposing, and developing photoresist to make a photoresist mask for the following etch or implant step. Block 608 is shown in dashed lines because pattern and implanting a channel stop, while preferred, is optional. The function of a channel stop may in some cases be performed by the bird's beak implant. However, a channel stop is preferred to further reduce source-to-drain leakage and is also desirable for some bird's beak mask geometries, such as those in which the BB pattern does not completely surround all moat regions. In block 610, a field oxide is grown outside the moat regions. The nitride mask layer and pad oxide are removed in block 612 to make a fresh surface for growing a thin gate oxide over the moat region in block 614. The bird's beak region is patterned and implanted in block 616. This is the preferred position in the sequence for the bird's beak pattern and implant step, as indicated in FIG. 6 by assigning it lower case Roman numeral (i). It is preferable to perform the bird's beak implant after growing the thick field oxide, because then the concentration can be well controlled, the doping not consumed or diffused by the oxidation process, and the lateral position well controlled in relation to the edges of the moat. However, there are several places within the process that are alternatives for performing a patterning and implanting step to dope the bird's beak region, indicated by Roman numerals (ii) through (v), which can be used in conjunction with different configurations of the BB mask as well as the CHSTOP mask in order to implement different doping profiles. After the bird's beak implant (and resist strip), a gate material, preferably polysilicon, but alternatively a metal, is deposited and doped if necessary to increase its conductivity in block 618. Then the gate is patterned and etched in block 620. The n-type source and drain regions are then patterned and implanted with one or more N+ dopants. Finally, the process ends with all additional steps required for completing the device, or an integrated circuit containing the device, being performed in block 624, which includes metallizations, interlayer dielectrics, protective overcoat, packaging, etc. The remainder of these processes required to create a device or integrated circuit are well known to those skilled in the art of semiconductor processing.

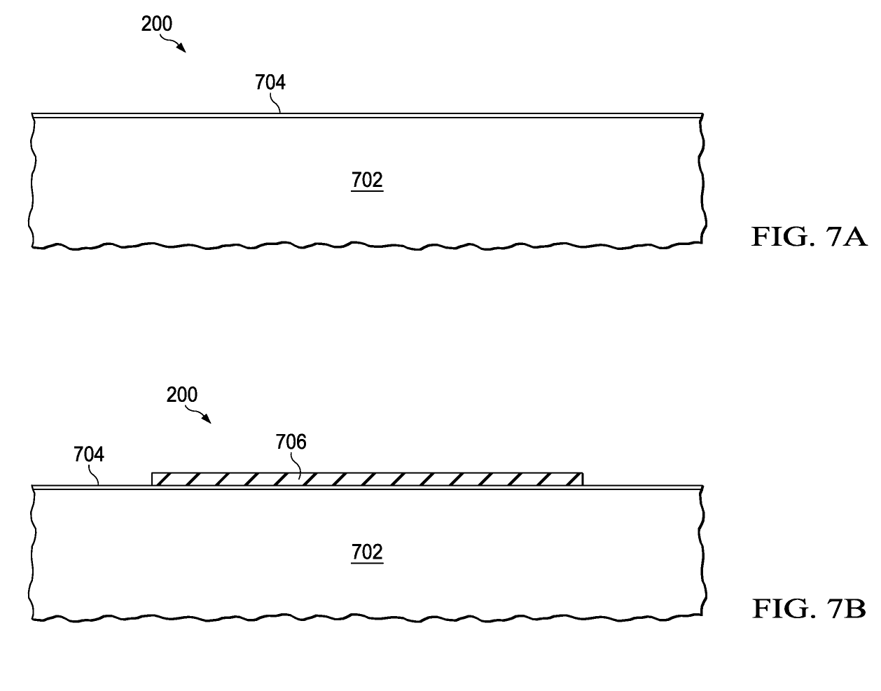

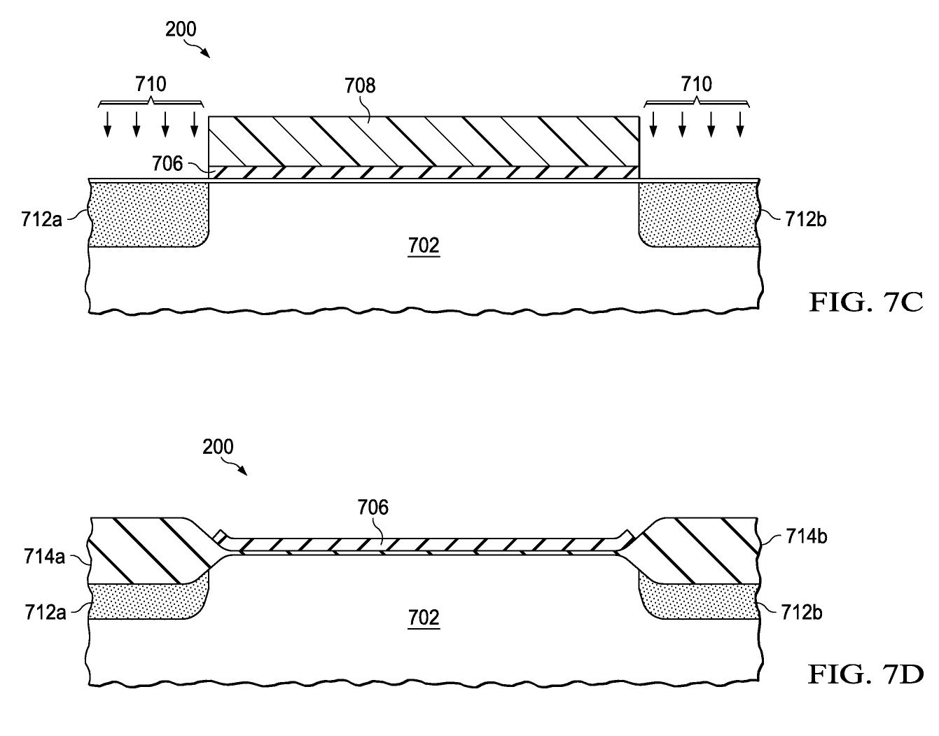

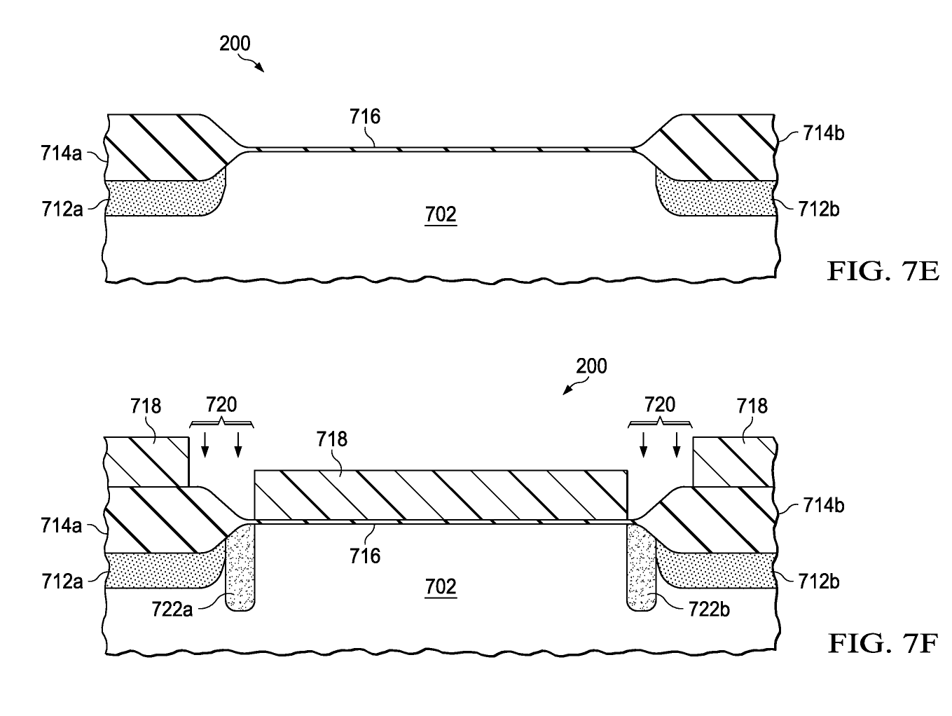

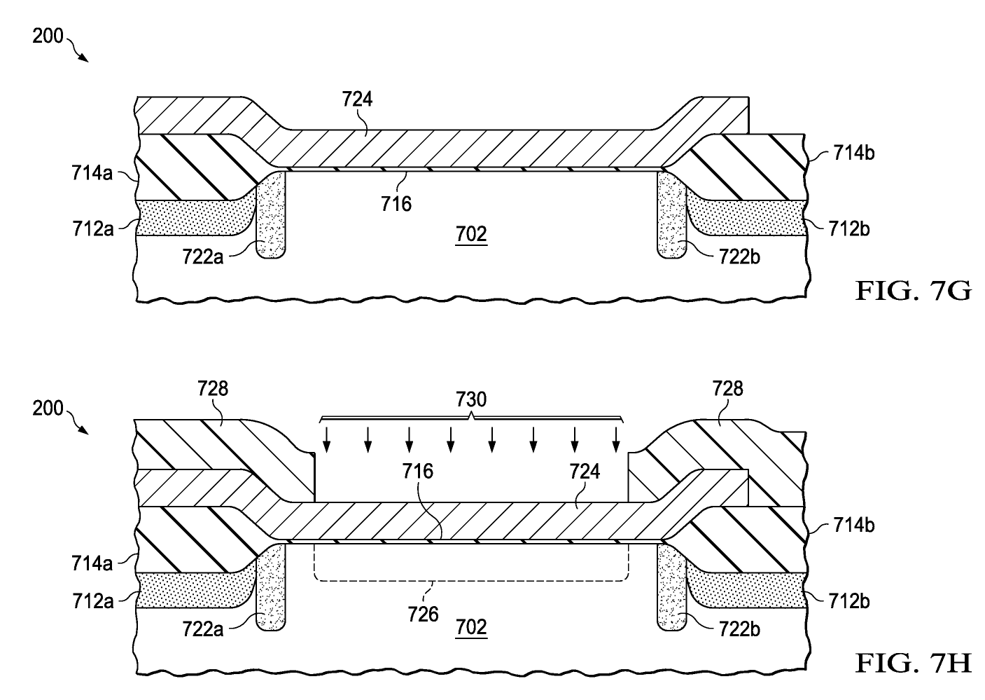

FIGS. 7A through 7H depict a series of cross-sectional views of an embodiment of a radiation hardened MOS device 200 similar to that shown in FIGS. 2A, 2B, and 2C, as fabricated using process 600. These views look in the same direction as the view in FIG. 2B, which shows cross-section A-A′ from FIG. 2A. FIGS. 7A through 7H show “snapshots” of a device taken at various steps during process 600. FIG. 7A shows the device after the start 602 of the process, showing substrate 702 with thin pad oxide layer 704 on it. Typical thickness of a pad oxide is 100 to 500 angstroms. FIG. 7B shows the device after block 606, showing a nitride layer deposited and etched to form the moat pattern. A typical nitride thickness is 1000 to 2000 angstroms. FIG. 7C shows the implantation of a channel stop during the implant phase of block 608, where photoresist masking layer 708 has been deposited, baked, and developed to form the channel stop pattern, and p-type ions 710 are in the process of being implanted through the open areas in the photoresist to form channel stop implanted regions 712a and 712b. Typical photoresist thicknesses are between 1 and 2 μm. Although in reality incident ions blanket the wafer, for clarity only the open areas where ions are getting through to the substrate are shown with arrows symbolizing the incident ions. FIG. 7D shows the results of step 610, after resist has been stripped and a thermal oxidation step has grown a thick field oxide shown as segments 714a on the left and 714b and on the right, leaving thinner channel stop regions 712a and 712b underlying the field oxide, and showing that the bird's beak region grows under the edge of the nitride mask 706, thereby pushing its edges upward slightly. It can also be seen that the channel stop doping does not extend inward to the thin oxide, due to the oxide encroachment under the nitride. In FIG. 7E, nitride and pad oxide have been removed in block 614, and gate oxide 716 has been grown over the moat region. FIG. 7F depicts the bird's beak implant step 616 during the implantation of p-type ions 720 through bird's beak photoresist mask 718 having openings over the bird's beak areas, and creating implanted regions 722a and 722b underneath the bird's beak regions. The bird's beak implant only penetrates the thinner areas of the tapered oxide within the bird's beak region, and thus it can be seen that the implanted regions 722a and 722b are typically narrower than the openings in the bird's beak mask 718. The gate 724 (typically polysilicon) is shown fully formed in FIG. 7G, which is a snapshot after step 620, gate 724 having been deposited, doped, patterned, and etched, and the resist stripped before this view. FIG. 7H shows the implanting of n-type dopants 730 through a patterned NSD photoresist mask 728 to form a source and drain, one of which 726 can be seen in dashed lines on the other side of the cross-section through the gate. After the resist is stripped, the state of the device after step 622 in process 600 would look like FIG. 2B.

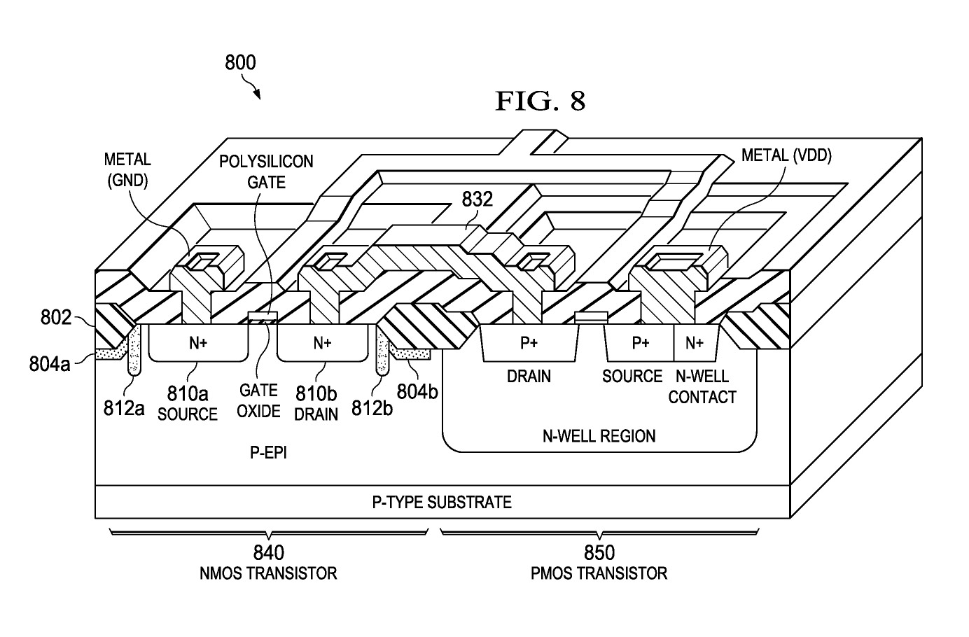

Referring now to FIG. 8, a portion of a CMOS integrated circuit (IC) 800 is shown in an isometric view cross-sectioned through two transistors 840 and 850. A completed radiation hardened NMOS transistor employing the designs and techniques of the present invention is shown generally located in the region indicated by 840, and a completed PMOS transistor made in an exemplary n-well process is shown generally located in the region indicated by 850. With respect to the NMOS transistor 840, features familiar from the cross-section shown in FIG. 2C are indicated, including field oxide 802, channel stop segments 804a and 804b, source 810a and drain 810b, and bird's beak implant regions 812a and 812b. It can be seen that p-type channel stop segment 804b is intentionally separated from the n-well of PMOS transistor 850 in order to maintain a high breakdown voltage of the PMOS transistor. In some processes, an n-type channel stop is provided under the field oxide proximate the PMOS transistors. In addition to features shown in FIG. 2C, further layers and structures needed to provide interconnection between various devices and protective overcoating of the circuitry are also shown in FIG. 8. As one example, metal interconnect 832 is shown making contact to drain regions in both transistors through contacts holes in a protective insulating SiO₂ layer. The structures illustrated in areas away from the radiation hardened NMOS transistor are merely exemplary, and any suitable similar integrated circuit structures and processes may be substituted.

According to one embodiment of the present invention, radiation hardened MOS devices with low radiation-induced leakage are provided that are suitable for application in NMOS, CMOS, or BiCMOS integrated circuits for operation in high-radiation environments, but with high breakdown voltages enabled by the device design. The devices provided by this invention may also be used in other applications requiring high breakdown voltage and low leakage. According to another embodiment of the present invention, a method for fabricating radiation hard MOS devices has been provided along with several alternatives for the placement of a step of patterning and implanting the bird's beak region to reduce leakage. According to a third embodiment of the present invention, an integrated circuit containing radiation hardened MOS devices fabricated using variations on a LOCOS process including minor layout changes and a bird's beak implant step has been provided. The concepts presented herein provide radiation hardened devices and circuits that exhibit lower radiation-induced leakage currents while maintaining high breakdown voltages and a minimal change in circuit density.

It will be appreciated that the present inventive method of fabricating radiation hardened MOS devices, which has originally been applied to fabricating NMOS devices within a CMOS or BiCMOS integrated circuit, is also applicable to fabricating other types of integrated circuits containing other devices including, for example, PMOS devices, bipolar junction transistors, diodes, resistors and capacitors. It should also be appreciated that such an integrated circuit is representative of only one suitable environment for use of the invention, and that the invention may be used in a multiple of other environments in the alternative. The invention should therefore not be limited to the particular implementations discussed herein.

Although preferred embodiments of the present invention have been described in detail, it will be understood by those skilled in the art that various modifications can be made therein without departing from the spirit and scope of the invention as set forth in the appended claims.

1. A radiation hardened MOS device having a width direction and a length direction, comprising:
a lightly-doped p-type silicon substrate having a top surface;
a field oxide overlying a portion of said substrate, said field oxide surrounding a moat region having edges at a boundary with an inner edge of said field oxide;
a gate oxide overlying said top surface of said substrate within said moat region said field oxide tapering to an interface with said gate oxide at said edges of said moat region, forming a tapered bird's beak region;
a heavily-doped p-type guard region underlying at least a portion of said bird's beak region, and having an inner edge terminating at said interface with said gate oxide;
a gate overlying said gate oxide and extending in said width direction across a first area of said moat region and crossing said bird's beak region in at least one place, said first area defining a channel area, and positioned so as to define second and third areas of said moat region, one on each side of said gate, said second and third areas defining a source area and a drain area, respectively; and
first and second n-type regions underlying said gate oxide in said moat region, one on each side of said gate in said source area and said drain area, respectively, each n-type region having an inner edge contiguous with said channel area along said width direction and having a predetermined electrical width along said inner edge, and having outer edges spaced by a gap from an inner edge of said p-type guard region, said first n-type region forming a source and said second n-type region forming a drain of the radiation hardened MOS device.

2. The radiation hardened MOS device as recited in claim 1, wherein said lightly-doped p-type substrate comprises a lightly-doped p-type layer or a lightly-doped p-type well formed within a top surface of a silicon substrate.

3. The radiation hardened MOS device as recited in claim 1, wherein said guard region further has an outer edge terminating under said field oxide.

4. The radiation hardened MOS device as recited in claim 1, further comprising a heavily-doped p-type channel stop region underlying said field oxide.

5. The radiation hardened MOS device as recited in claim 4, wherein said guard region has an outer edge that is contiguous with an inner edge of said channel stop region.

6. The radiation hardened MOS device as recited in claim 1, wherein said gap has a first spacing in said width direction and a different second spacing in said length direction.

7. The radiation hardened MOS device as recited in claim 1, wherein said guard region underlies a portion of said bird's beak region directly under said gate and extending a predetermined distance along the length direction on either side of the gate, such that a total length of said guard region is less than or equal to a total length of the moat region.

8. A method of fabricating a radiation hardened MOS device having a predetermined electrical width defined in a width direction, comprising the steps of:
(a) providing a silicon substrate having a top surface, a “P−” layer extending from said top surface into the substrate, and a pad oxide layer on said top surface;
(b) forming a masking layer on said top surface to define a moat region covered by said masking layer;
(c) oxidizing said substrate to form a field oxide layer in areas not covered by said masking layer, terminating in a bird's beak region extending beneath said masking layer;
(d) removing said masking layer and said pad oxide;
(e) forming a gate oxide on said top surface within said moat region;
(f) implanting a p-type impurity into said substrate beneath said bird's beak region but not extending under said gate oxide;
(g) forming a gate overlying said gate oxide and extending in said width direction across a first portion of said moat region defining a channel area, said gate further extending across said bird's beak region onto said field oxide layer on at least one edge of said moat region and having a gate length along said at least one edge defined where said gate crosses said edge, in a length direction defined to be the direction parallel to said edge;
(h) implanting an n-type impurity into said substrate beneath said gate oxide and within said moat region to form a source region and a drain region, outer edges of said source region and drain region being spaced away from said bird's beak region by a gap, said source region and drain region having a width along said channel area equal to said predetermined electrical width; and
(i) completing fabrication of said radiation hardened MOS device on said substrate.

9. The method as recited in claim 8, wherein said “P−” layer extends throughout an entire thickness of said silicon substrate.

10. The method as recited in claim 8, wherein said masking layer is silicon nitride.

11. The method as recited in claim 8, further comprising the step of forming a heavily-doped p-type channel stop region underlying said field oxide layer.

12. The method as recited in claim 8, wherein said gap is greater than one micrometer.

13. The method as recited in claim 8, wherein said gap has a first spacing in said length direction and a different second spacing in said width direction.

14. The method as recited in claim 8, wherein said p-type impurity is boron.

15. The method as recited in claim 8, wherein step (f) comprises implanting said p-type impurity into said substrate beneath a region including said bird's beak region and extending at least partially beneath said field oxide layer.

16. The method as recited in claim 8, wherein step (f) comprises implanting said p-type impurity into said substrate beneath said bird's beak region and underlying said gate in an area including width of said bird's beak region in said width direction and extending in said length direction from under said gate by a predetermined length in either direction along an edge of said moat region.

17. The method as recited in claim 16, wherein said predetermined length is greater than one micrometer.

18. The method as recited in claim 8, wherein the step of implanting a p-type impurity occurs in sequence between steps (c) and (d), or between steps (b) and (c), or between steps (a) and (b).

19. The method as recited in claim 8, wherein said radiation hardened MOS device is an NMOS integrated circuit, a CMOS integrated circuit, or a BiCMOS integrated circuit.

20. An integrated circuit (IC) device comprising:
one or more devices selected from the group consisting of a PMOS transistor, a bipolar junction transistor (BJT), a resistor, and a capacitor; and
a radiation hardened MOS device having a width direction and a length direction,
wherein said radiation hardened MOS device comprises a lightly-doped p-type silicon substrate having a top surface, a field oxide overlying a portion of said substrate, said field oxide surrounding a moat region having edges at a boundary with an inner edge of said field oxide, a gate oxide overlying said top surface of said substrate within said moat region, said field oxide tapering to an interface with said gate oxide at said edges of said moat region, forming a tapered bird's beak region, a heavily-doped p-type guard region underlying at least a portion of said bird's beak region, and having an inner edge terminating at said interface with said gate oxide, a gate overlying said gate oxide and extending in said width direction across a first area of said moat region and crossing said bird's beak region in at least one place, said first area defining a channel area, and positioned so as to define second and third areas of said moat region, one on each side of said gate, said second and third areas defining a source area and a drain area, respectively, and first and second n-type regions underlying said gate oxide in said moat region, one on each side of said gate in said source area and said drain area, respectively, each n-type region having an inner edge contiguous with said channel area along said width direction and having a predetermined electrical width along said inner edge, and having outer edges spaced by a gap from an inner edge of said p-type guard region, said first n-type region forming a source and said second n-type region forming a drain of the radiation hardened MOS device.
